(19) United States
(12) Patent Application Publication
(10) Pub. No.: US 2022/0254573 A1
(43) Pub. Date: Aug. 11, 2022

(54) DYE-SENSITIZED SOLAR CELL

(71) Applicant: SHARP KABUSHIKI KAISHA, Sakai City, Osaka (JP)

(72) Inventors: ATSUSHI FUKUI, Sakai City, Osaka (JP); KEI KASAHARA, Sakai City, Osaka (JP); TOMOHISA YOSHIE, Sakai City, Osaka (JP); DAISUKE TOYOSHIMA, Sakai City, Osaka (JP)

(21) Appl. No.: 17/630,333

(22) PCT Filed: Jul. 22, 2020
(86) PCT No.: PCT/JP2020/028431

§ 371 Date: Jan. 26, 2022

(30) Foreign Application Priority Data
Jul. 26, 2019 (JP) 2019-137939

(51) Int. Cl. H01G 9/20

(52) U.S. Cl. CPC H01G 9/2036; H01G 9/2059; H01L 51/0067; H01G 9/2031; H01G 9/2018

(57) ABSTRACT

A dye-sensitized solar cell (100) includes: a first electrode containing first metal oxide particles and including a porous semiconductor layer (16A) carrying dye; a second electrode acting as a counter electrode of the first electrode; and a porous insulating layer (36A) provided between the first electrode and the second electrode, the porous insulating layer (36A)(i) holding an electrolytic solution (42) containing a redox couple and a pyrazole-based compound, and (ii) containing second metal oxide particles.

### TECHNICAL FIELD

The present disclosure relates to a dye-sensitized solar cell.

### BACKGROUND ART

Solar cells are classified into three kinds according to materials: the silicon solar cell, the compound solar cell, and the organic solar cell. The silicon solar cell is high in conversion efficiency, and solar cells made of polysilicon are most widely available for solar power generation. The dye-sensitized solar cell (hereinafter abbreviated as “DSC”) is a kind of organic solar cells. The DSC is lower in conversion efficiency than the silicon solar cell; however, the DSC is lower in production cost than the silicon solar cell and the compound solar cell using inorganic semiconductors. This advantage of the DSC is attracting attention in recent years. Another advantage of the DSC attracting attention is that, in a low-light environment, the DSC is more efficient in power generation than the silicon solar cell.

Patent Documents 1 to 3 disclose dye-sensitized solar cells including an electrolyte solution containing a pyrazole-based compound. The electrolyte solution containing a pyrazole-based compound reduces a reverse current that could flow regardless of emitting light, making it possible to increase an open circuit voltage of the DSC.

### CITATION LIST

### Patent Literature

Patent Document 1: Japanese Unexamined Patent Application Publication No. 2003-331936

Patent Document 2: Japanese Unexamined Patent Application Publication No. 2004-047229

Patent Document 3: Japanese Unexamined Patent Application Publication No. 2005-216490

### SUMMARY OF INVENTION

### Technical Problem

A study of the inventors of the present invention shows that when the DSC is heated at a temperature of approximately 80° C. or higher, an open circuit voltage Voc and a short circuit current Jsc fall. One of the reasons is that the heat resistance of the pyrazole-based compound is far from satisfactory. In particular, when the temperature of the DSC rises, the electrolyte solution containing the pyrazole-based compound alone is not sufficiently effective in curbing the falls of the open circuit voltage and the short circuit current. When the DSC is provided with greater durability to heat; that is, greater heat resistance, effects are expected of curbing the falls of the open circuit voltage and the short circuit current.

In view of the above problem, the present disclosure is intended to provide a dye-sensitized solar cell capable of appropriately curbing falls of an open circuit voltage Voc and a short circuit current Jsc.

### Solution to Problem

In order to solve the above problem, a dye-sensitized solar cell according to an aspect of the present disclosure includes: a first electrode containing first metal oxide particles and including a porous semiconductor layer carrying dye; a second electrode acting as a counter electrode of the first electrode; and a porous insulating layer provided between the first electrode and the second electrode, the porous insulating layer (i) holding an electrolytic solution containing a redox couple and a pyrazole-based compound, and (ii) containing second metal oxide particles.

### Advantageous Effects of Invention

An exemplary embodiment of the present invention provides a novel dye-sensitized solar cell capable of appropriately curbing falls of an open circuit voltage Voc and a short circuit current Jsc.

### BRIEF DESCRIPTION OF DRAWINGS

FIG. 1 is a schematic cross-sectional view of a DSC 100 according to this embodiment.

FIG. 2 is a schematic cross-sectional view of a DSC 200 according to a comparative example.

FIG. 3 is a view of a pyrazole-based compound eccentrically distributed near a surface of a counter electrode conductive layer 28.

### DESCRIPTION OF EMBODIMENT

Before an embodiment of the present invention is described, described below with reference to FIG. 3 are findings discovered by the inventors of the present invention as a basis of the present invention.

FIG. 3 is a schematic cross-sectional view of a DSC 200 having a conventional sandwich cell structure. The DSC 200 includes: a substrate 12 transparent to light; a transparent conductive layer 14 formed on the substrate 12; and a porous semiconductor layer 16 formed on the transparent conductive layer 14. The porous semiconductor layer 16 includes semiconductor fine particles and pores, and carries dye (not shown). The porous semiconductor layer 16 is formed of, for example, titanium oxide.

The DSC 200 further includes: a substrate 22 transparent to light; a transparent conductive layer 24 formed on the substrate 22; and a counter electrode conductive layer 28 formed on the transparent conductive layer 24. Between the porous semiconductor layer 16 and the counter electrode conductive layer 28, an electrolytic solution (an electrolyte solution) 42 is filled. The electrolytic solution 42 is filled in a clearance between the substrate 12 and the substrate 22, and the clearance is sealed with a seal 52. The electrolytic solution 42 contains, for example, I⁻ and I₃⁻ as mediators (redox couples). The seal 52 is formed of photopolymer or thermosetting polymer. The porous semiconductor layer 16 functions as a positive electrode, and the counter electrode conductive layer 28 functions as a negative electrode. As can be seen, the cell structure including the positive electrode and the negative electrode attached together is commonly referred to as a sandwich cell structure. The DSCs disclosed in Patent Documents 1 to 3 have the sandwich cell structure.

A problem of DSCs is that they are not resistant to heat. In particular, when a DSC is subjected to a test that complies with a heat resistant test B-1 (High-Temperature Storage Test: at 85±2° C.) of JIS 8938, its performance significantly deteriorates. When a DSC is heated at a temperature of approximately 80° C. or above, a redox couple I₃⁻ in the electrolytic solution decomposes into I₂ and I⁻. I₂ is adsorbed onto the surface of the porous semiconductor layer 16 formed of titanium oxide and acts as a current leakage source. It is this current leakage source that decreases the open circuit voltage Voc and the short circuit current Jsc.

When a pyrazole-based compound is added to the electrolytic solution of the DSCs disclosed in Patent Documents 1 to 3, the pyrazole-based compound certainly binds with I₂, and makes it possible to keep I₂ from being adsorbed onto the surface of the titanium oxide. Such a property of the pyrazole-based compound reduces leakage of electrons from the surface of the porous semiconductor layer toward the redox couple I₃⁻. Expected as a result is a rise of the open circuit voltage Voc.

According to a study of the inventors, a hydrogen element (proton), which binds with a first nitrogen element of the pyrazole-based compound in the electrolytic solution, is likely to desorb. Hence, the pyrazole-based compound releases a hydrogen group, and is likely to be charged negatively. Moreover, in the case of a sandwich DSC, the counter electrode is likely to be charged positively. Hence, the pyrazole-based compound releasing the hydrogen group and charged negatively is attracted toward, and eccentrically distributed near, the positively charged counter electrode in a rectangular region 50 illustrated in FIG. 3. As a result, in the electrolytic solution near the surface of the porous semiconductor layer across from the counter electrode, the concentration of the pyrazole-based compound decreases. Hence, the pyrazole-based compound is less likely to react to I₂ in the pores of the titanium oxide.

As can be seen, a problem of the sandwich cell structure is that, even if the pyrazole-based compound is added to the electrolytic solution, the added pyrazole-based compound fails to achieve a sufficient effect of appropriately reducing leakage of a current from the surface of the porous semiconductor layer to the redox couple I₃⁻. Moreover, the heat resistance of the pyrazole-based compound is far from satisfactory.

According to the above findings, the inventors of the present invention has found out how to improve the phenomenon of the pyrazole-based compound eccentrically distributed near the counter electrode, using a porous insulating layer and a counter electrode conductive layer stacked on the porous semiconductor layer; that is, adopting a monolithic cell structure. Hence, the inventors have arrived at the present invention.

In a non-limiting and exemplary embodiment, a dye-sensitized solar cell of the present invention includes: a first electrode containing first metal oxide particles and including a porous semiconductor layer carrying dye; a second electrode acting as a counter electrode of the first electrode; and a porous insulating layer provided between the first electrode and the second electrode. The porous insulating layer holds an electrolytic solution containing a redox couple and a pyrazole-based compound, and contains second metal oxide particles. The first electrode includes at least a porous semiconductor layer carrying dye, and may further include a conductive layer. The first electrode is also referred to as a photoelectrode. The second electrode functions as a counter electrode of the photoelectrode, and is also simply referred to as a counter electrode. The counter electrode includes at least a counter electrode conductive layer, and may further include a catalyst layer. The counter electrode conductive layer may also serve as the catalyst layer.

In a module including a plurality of integrated dye-sensitized solar cells (unit cells, or simply referred to as a “cell”), for example, neighboring cells are connected together electrically in series or in parallel. Here, for example, the cells share the transparent conductive layer formed on a substrate so that a photoelectrode of one of the cells is connected to a counter electrode of the other cell. A typical example of the cell structure of the dye-sensitized solar cell according to this embodiment is a monolithically integrated structure.

Described below is an embodiment of the present invention, with reference to the attached drawings. Note that descriptions to be detailed more than necessary may be omitted. For example, descriptions of details well known in the art and substantially identical features may be omitted. This is to keep succeeding descriptions from redundancy, and facilitate understanding of those skilled in the art. The inventors of the present invention provide the descriptions below and the drawings attached thereto to help those skilled in the art thoroughly understand the present invention. The descriptions and the drawings do not intend to limit the subject matter of the claims. In the descriptions below, like reference signs designate identical or corresponding features. The aspects in the embodiment to be described below are examples by any means. Unless otherwise technically contradictory, these aspects can be combined in various manners.

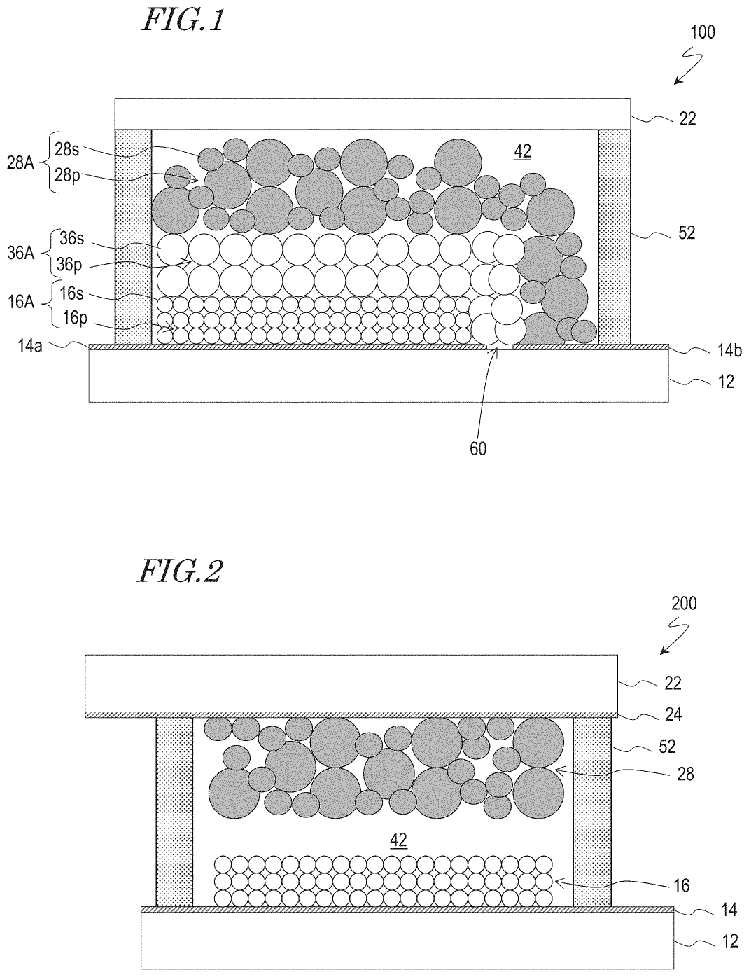

FIG. 1 is a schematic cross-sectional view of a DSC 100. The DSC 100 has a monolithic cell structure. The DSC 100 includes: a substrate 12 transparent to light; a transparent conductive layer 14a formed on the substrate 12; a porous semiconductor layer 16A formed on the transparent conductive layer 14a; a porous insulating layer 36A covering the porous semiconductor layer 16A; a transparent conductive layer 14b formed on the substrate 12; a counter electrode conductive layer 28A formed on the porous insulating layer 36A; and a substrate 22 transparent to light.

The porous semiconductor layer 16A and the counter conductive layer 28A are arranged across the porous insulating layer 36A from each other to face in as large area as possible. The counter electrode conductive layer 28A is electrically connected to the transparent conductive layer 14b formed on the substrate 12. The substrate 12 is provided with a scribe line 60 electrically separating the transparent conductive layer 14a from the transparent conductive layer 14b. That is, the transparent conductive layer 14a and the transparent conductive layer 14b are insulated from each other on the substrate 12.

A clearance between the substrate 12 and the substrate 22 is filled with an electrolytic solution 42, and hermetically sealed with a seal 52. The electrolytic solution 42 permeates throughout the porous semiconductor layer 16A, the porous insulating layer 36A, and the counter electrode conductive layer 28A. The electrolytic solution 42 contains, for example, I— and I₃— as redox couples. The seal 52 is formed of photopolymer or thermosetting polymer.

The substrates 12 and 22 can be made of, for example, a glass substrate and a flexible film. Note that the substrates 12 and 22 may be formed of a material substantially transparent to light whose wavelength has sensitivity effective to the dye to be described later. The material does not have to be transparent to lights in all the wavelengths. The substrates 12 and 22 have a thickness of, for example, 0.2 mm or more and 5.0 mm or less. Note that the substrate 22 does not have to be transparent to light.

The substrates 12 and 22 may be made of a substrate material commonly used for solar cells. An example of the substrate material may include a glass substrate made of such glass as soda glass, fused silica glass, or crystalline silica glass. Alternatively, the example may include a heat-resistant resin plate such as a flexible film. An example of the flexible film includes tetraacetylcellulose (TAC), polyethylene terephthalate (PET), polyphenylenesulfide (PPS), polycarbonate (PC), polyarylate (PA), polyetherimide (PEI), phenoxy resin, or Teflon (registered trademark).

The transparent conductive layers 14a and 14b are commonly used for solar cells, and formed of a material electrically conductive and transparent to light. Examples of such a material include at least one of the materials selected from a group of indium tin oxide (ITO), tin dioxide (SnO₂), fluorine-doped tin oxide (FTO), and zinc oxide (ZnO). The transparent conductive layers 14a and 14b have a thickness of, for example, 0.02 μm or more and 5.00 μm or less. An electrical resistance of the transparent conductive layers 14a and 14b is preferably low, an example of which is preferably 40Ω/□ or below.

The porous semiconductor layer 16A includes semiconductor fine particles (first metal oxide particles) 16s and pores 16p, and carries dye (not shown). The porous semiconductor layer 16A is a porous semiconductor-particle aggregate made of, for example, titanium oxide.

The porous semiconductor layer 16A is formed of a photoelectric conversion material. Examples of such a material include at least one of the materials selected from a group of titanium oxide, zinc oxide, tin oxide, iron oxide, niobium oxide, cerium (IV) oxide, tungsten (VI) oxide, barium titanate, strontium titanate, cadmium sulfide, lead (II) sulfide, zinc sulfide, indium phosphide, copper indium sulfide (CuInS₂), CuAO₂, and SrCu₂O₂. Preferably used among the materials is titanium oxide in view of high stability and a large band gap of titanium oxide itself.

An example of titanium oxide includes (i) various kinds of titanium oxide in a narrow definition such as anatase titanium oxide, rutile titanium oxide, amorphous titanium oxide, metatitanate, and orthotitanate, (ii) titanium hydroxide, or (iii) hydrous titanium oxide. These titanium oxides are used alone or in combination. The two crystalline titanium oxides; that is, anatase titanium oxide and rutile titanium oxide, can be produced in either form, depending on a production technique and thermal history. However, crystalline titanium oxide is commonly anatase titanium oxide. In view of sensitization of dye, the titanium oxide to be used preferably contains a high percentage of anatase titanium oxide; that is, for example, 80% or more of anatase titanium oxide.

The crystalline semiconductor may be either monocrystalline semiconductor or polycrystalline semiconductor. In view of stability, crystal growth rate, and production costs, polycrystalline semiconductor is preferable. Polycrystalline nanoscale or microscale semiconductor fine particles are preferably used. Hence, titanium oxide fine particles are preferably used as a primary material of the porous semiconductor layer 16A. The titanium oxide fine particles can be manufactured by, for example, liquid phase separation such as thermal synthesis or use of sulfuric acid, or vapor deposition. Moreover, the titanium oxide fine particles can be produced of chloride developed by Degussa and subjected to high-temperature hydrolysis.

The semiconductor fine particles may be a single semiconductor compound or different semiconductor compounds including a mixture of particles in two or more particle sizes. The semiconductor fine particles having a large particle size would cause incident light to scatter to contribute to an increase in a rate of catching light, and the semiconductor fine particles having a small particle size would provide more adsorption points to contribute to an increase in the amount of dye to be adsorbed.

If the semiconductor fine particles are a mixture of fine particles with different particle sizes, an average particle size rate among the fine particles in the same size is preferably 10 times or more. An average particle size of the fine particles with a large particle size is, for example, 10 nm or more and 500 nm or less. An average particle size of the fine particles with a small particle size is, for example, 5 nm or more and 100 nm or less. If the semiconductor fine particles to be used are a mixture of different semiconductor compounds, it is effective to have the semiconductor compound of a higher adsorption property with a small particle size.

The porous semiconductor layer 16A has a thickness of, for example, 0.1 μm or more and 100.0 μm or less. Moreover, the porous semiconductor layer 16A has a specific surface area of, for example, 10 m²/g or more and 200 m²/g or less.

As the dye to be carried with the porous semiconductor layer 16A, selectively used can be one or two or more kinds of organic dyes and metallic complex dyes with absorption in the visible light or infrared light range.

Examples of the organic dyes include at least one of the dyes selected from a group of an azo-based dye, a quinone-based dye, a quinoneimine-based dye, a quinacridone-based dye, a squarylium-based dye, a cyanine-based dye, a merocyanine-based dye, a triphenylmethane-based dye, a xanthene-based dye, a porphyrin-based dye, a perylene-based dye, an indigo-based dye, and a naphthalocyanine-based dye. Organic dyes are typically larger in absorptivity than metallic complex dyes whose molecules coordinate-bond to a transition metal such as ruthenium.

A metallic complex dye is formed of molecules coordinate-bonding to metal. The molecules are of; for example, a porphyrin-based dye, a phthalocyanine-based dye, a naphthalocyanine-based dye, or a ruthenium-based dye. Examples of the metal include at least one of the metals selected from a group of Cu, Ni, Fe, Co, V, Sn, Si, Ti, Ge, Cr, Zn, Ru, Mg, Al, Pb, Mn. In, Mo, Y, Zr, Nb, Sb, La, W, Pt, TA, Ir, Pd, Os, Ga, T, Eu, Rb, Bi, Se, As, Sc, Ag, Cd, Hf, Re, Au, Ac, Tc, Te, and Rh. Preferably used as the metallic complex dye is a phthalocyanine-based dye or a ruthenium-based dye coordinating with metal. In particular, the ruthenium-based metallic complex dye is preferably used.

The ruthenium-based metallic complex dye to be used may be a commercially available one. An example of the ruthenium-based metallic complex dye includes a dye made by Solaronix under the trade name of Ruthenium 535, Ruthenium 535-bisTBA, or Ruthenium 620-1H3TBA.

The porous semiconductor layer 16A may carry a co-adsorbent. When the porous semiconductor layer 16A contains the co-adsorbent, the co-adsorbent keeps the sensitized dye from associating or coagulating in the porous semiconductor layer 16A. The co-adsorbent may appropriately be selected from among typical materials of this field, in accordance with a sensitized dye to be combined with the co-adsorbent.

The porous insulating layer 36A is formed on the porous semiconductor layer 16A to cover the whole the porous insulating layer 16A. The porous insulating layer 36A is positioned between the porous insulating layer 16A and the counter electrode conductive layer 28A, and separates the two layers from each other. Moreover, the porous insulating layer 36A is disposed to fill the gap between the transparent conductive layers 14a and 14b and to insulate the two transparent conductive layers from each other. The porous insulating layer 36A holds the electrolytic solution 42 containing a redox couple and a pyrazole-based compound. The porous semiconductor layer 36A further includes insulating fine particles (second metal oxide particles) 36 and pores 36p.

The porous insulating layer 36A stacked on the porous semiconductor layer 16A is preferably thinner than the porous semiconductor layer 16A. For example, the porous insulating layer 36A has a film thickness of preferably 0.2 μm or more and 20 μm or less, and more preferably, 1 μm or more and 10 μm or less.

The electrolytic solution 42 is injected mainly into, and held within, the pores 36p of the porous insulating layer 36A. The insulating fine particles 36s can be formed of at least one of the substances selected from a group of, for example, titanium oxide, niobium oxide, zirconium oxide, magnesium oxide, silicon oxide such as silica glass or soda glass, aluminum oxide, and barium titanate. Preferably used are insulating fine particles of such substances as titanium oxide and zirconium oxide doped with Al or Mg. Moreover, the insulating fine particles 36s are preferably rutile titanium oxide. When the insulating fine particles 36s are rutile titanium oxide, an average particle size of the rutile titanium oxide is preferably 5 nm or more and 500 nm or less, and more preferably, 10 nm or more and 300 nm or less.

A groove of the scribe line 60 is preferably filled with the insulating fine particles 36s. Such a feature can certainly insulate the transparent conductive layer 14a and the transparent conductive layer 14b from each other on the substrate 12.

The electrolytic solution 42 may be a fluid substance (a fluid) containing a redox couple, and shall not be limited to a particular fluid substance as long as the fluid substance can be used for such cells as a typical cell or a dye-sensitized solar cell. Specifically, the electrolytic solution 42 includes a liquid made of a redox couple and a solvent capable of dissolving the redox couple, a liquid made of a redox couple and molten salt capable of dissolving the redox couple, and a liquid made of a redox couple and a solvent and molten salt capable of dissolving the redox couple. The electrolytic solution 42 may contain a gelling agent to turn into gel.

Examples of the redox couple include an I/If-based redox couple, a Br₂⁻/Br₃⁻-based redox couple, an Fe₂⁺/Fe₃⁺-based redox couple, and a quinone/hydroquinone-based redox couple. More specifically, the redox couple can be a combination of metal iodide and iodine (I₂). The metal iodide includes such substances as lithium iodide (Li), sodium iodide (NaI), potassium iodide (KI), and calcium iodide (CabI). Furthermore, the redox couple can be a combination of tetraalkyl ammonium salt and iodine. The tetraalkyl ammonium salt includes such substances as tetraethylammonium iodide (TEAI), tetrapropylammonium iodide (TPAI), tetrabutylammonium iodide (TBAI), and tetrahexylammonium iodide (THAI). Moreover, the redox couple may be a combination of metal bromide and bromine. The metal bromide includes such substances as lithium bromide (LiBr), sodium bromide (NaBr), potassium bromide (KBr), calcium bromide (CaBr₂). As the redox couple, a combination of LiI and I₂ is preferably used.

Preferably, an example of the solvent for the redox couple contains at least one of the compounds selected from a group of a carbonate compound such as ethylene carbonate and propylene carbonate, a lactone compound such as γ-butyrolactone and γ-valerolactone, a nitrile compound such as 3-methoxypropionitrile and acetonitrile. When a pyrazole-based compound is added to the electrolytic solution 42, it is preferable to use a solvent having a relative permittivity of 20 or higher and 80 or lower. A particularly preferable solvent to be used is γ-butyrolactone having a high permittivity.

Preferably, the pyrazole-based compound is expressed by a general expression (1) below, wherein each of elements R¹ is independent and one of the substances selected from a group of a hydrogen atom, a lower alkyl group, a halogen group, an amino group, a phenyl group, a furyl group, a methoxyphenyl group, a thienyl group, and a methylphenyl group, and wherein all the elements R¹ may be of the same group. Here, the lower alkyl group is defined as an alkyl group with 1 to 5 carbons.

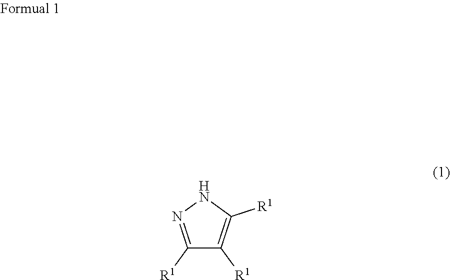

The pyrazole-based compound is, for example, pyrazole expressed by a general expression (2-1), 3-methylpyrazole expressed by a general expression (2-2), or 3, 5-dimethylpyrazole expressed by a general expression (2-3). The pyrazole-based compound in the electrolytic solution 42 has a molar concentration of preferably 0.1 M or higher and 1.5 M or lower, and more preferably, 0.3 M or higher and 1.2 M or lower. When the molar concentration of the pyrazole-based compound in the electrolytic solution 42 exceeds 1.5 M, the viscosity of the pyrazole-based compound becomes higher. Hence, a temperature of the porous insulating layer 36A is likely to be high.

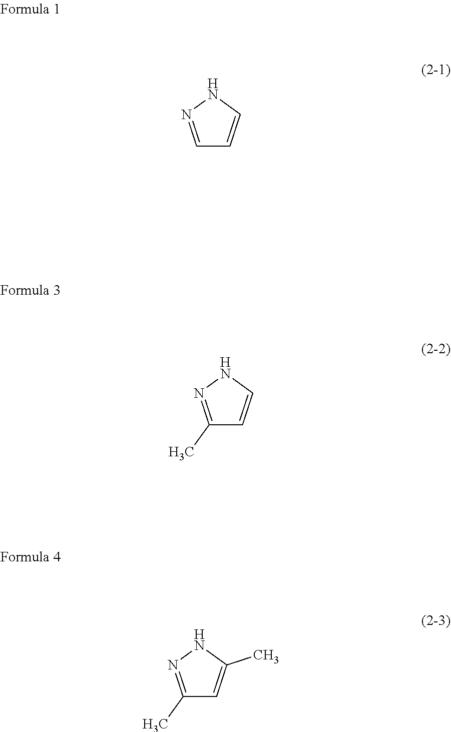

Many of pyrazole-based compounds are commonly high in viscosity. Hence, when a pyrazole-based compound is applied to a monolithic cell structure, a concern is that an electrical resistance of the cell would increase (the resistance of the cell increases).

A study of the inventors of the present invention shows that the average particle size of the insulating fine particles 36s is preferably larger than an average particle size of the semiconductor fine particles 16s, and a porosity a of the porous insulating layer 36A is preferably higher than a porosity b of the porous semiconductor layer 16A. Such a relationship can reduce a possible increase in the resistance of the cell caused by the addition of the pyrazole-based compound. Here, the porosity a is defined as a percentage of the volume of the pores 36p to the whole volume of the porous insulating layer 36A. The porosity b is defined as a percentage of the volume of the pores 16p to the whole volume of the porous semiconductor layer 16A. The average particle size of the insulating fine particles 36s is particularly preferably 100 μm or more and 500 μm or less.

The counter electrode conductive layer 28A, supported by the substrate 22, is a counter electrode of the porous semiconductor layer 16A. The counter electrode conductive layer 28A, which covers the whole porous insulating layer 36A, is formed on the porous insulating layer 36A to electrically connect to the transparent conductive layer 14b on the substrate 12. The counter electrode conductive layer 28A includes, for example, carbon fine particles 28s and pores 28p.

The counter electrode conductive layer 28A can be formed of a conductive material and a catalyst material. An exemplary material of the counter electrode conductive layer 28A is at least one of the materials selected from a group of precious metal materials such as platinum and palladium, and carbon-based materials such as graphite, carbon black, Ketjen black, carbon nanotube, and fullerene.

The counter electrode conductive layer 28A has a thickness of, for example, 0.1 μm or more and 100.0 μm or less. Moreover, the counter electrode conductive layer 28A has a specific surface area of for example, 10 m²/g or more and 200 m²/g or less.

The DSC 100 can be produced by a publicly known technique except that the electrolytic solution 42 to be injected is prepared to contain a pyrazole-based compound. For example, the DSC 100 can be produced by a technique cited in WO 20141038570. The present application incorporates the content of WO 2014/038570 by reference in its entirety.

In the DSC according to this embodiment, the porous insulating layer 36A and the counter electrode conductive layer 28A are stacked on the porous semiconductor layer 16A. The monolithic cell structure can reduce a phenomenon in which positive electric charges appearing on the surface of the counter electrode conductive layer 28A are weakened by the porous insulating layer 36A, and the pyrazole-based compound charged negatively is attracted toward the counter electrode 28A. Moreover, the pyrazole-based compound is likely to be adsorbed onto the surface of the porous insulating layer 36A formed of a metal oxide. That is why the pyrazole-based compound is less likely to be attracted toward the counter electrode 28A. Such actions keep the pyrazole-based compound from eccentrically distributing near the counter electrode 28A.

The present disclosure will be described more specifically, with reference to experimental examples (Examples 1 to 5 and Comparative Example 1). In the examples, dye-sensitized solar cells having the structure of the DSC 100 were produced in accordance with a production method to be described below.

### EXAMPLES

### 1. Forming Monolithically Stacked Product

A commercially available titanium oxide paste (produced by Solaronix SA under a product name Ti-Nanoxide D/SP with an average particle size of 13 nm) was applied with a doctor blade to the substrate (produced by Nippon Sheet Glass Company Ltd.) provided with a film of SnO₂ doped with fluorine and serving as the transparent conductive layers 14a and 14b.

Next, the substrate coated with the titanium oxide paste was preliminarily dried for 30 minutes at a temperature of 100° C., and, after that, baked for 40 minutes at a temperature of 500° C. This step was repeated twice, and a substrate was obtained. The obtained substrate was provided with a titanium oxide film (having a film thickness of 12 μm) serving as the porous semiconductor layer 16A.

Next, ethanol was added to an aqueous dispersion into which commercially available zirconium oxide particles (produced by C.I. Takiron Corporation) were dispersed. Hence, a dispersion liquid was prepared. A solvent of this dispersion liquid was substituted with terpineol and mixed with ethyl cellulose, so that the viscosity of the solvent was adjusted. Thus, a paste containing zirconium oxide powder was produced. The paste was applied with a doctor blade onto the substrate provided with the titanium oxide film.

After that, the substrate coated with the paste containing zirconium oxide powder was preliminarily dried for 30 minutes at a temperature of 100° C., and, after that, baked for 40 minutes at a temperature of 500° C. Hence, a substrate was obtained. The obtained substrate was provided with a zirconium oxide film (having a film thickness of 6 μm) formed on the porous semiconductor layer 16A and serving as the porous insulating layer 36A.

Next, platinum particles (produced by Furuya Metal Co. Ltd.) were dispersed into terpineol, and a paste containing platinum powder was prepared. The paste was applied with a doctor blade onto the substrate provided with the zirconium oxide film. The substrate coated with the paste was preliminarily dried for 30 minutes at a temperature of 100° C., and, after that baked for 30 minutes at a temperature of 500° C. Thus, a monolithically stacked product was obtained. In the monolithically stacked product, the porous insulating layer 36A and the counter electrode conductive layer 28A were stacked on the porous semiconductor layer 16A. The counter conductive layer 28A, which was stacked on the porous insulating layer 36A, had a thickness of 0.1 μm.

2. Adsorbing Dye onto Stacked Product

The FSD 19 dye was dissolved into ethanol, and a dye adsorption solution having a concentration of 4×10⁻⁴ M was prepared. The stacked product was immersed in the dye adsorption solution for 80 hours at a room temperature. After that, the stacked product was washed with ethanol and dried for approximately five minutes at a temperature of approximately 60° C. Thus, the substrate 12 was obtained. The substrate 12 was provided with the porous semiconductor layer 16A carrying the dye.

### 3. Preparing Electrolytic Solution

Iodine having a concentration of 0.05 M (produced by Sigma-Aldrich Co. LLC), dimethylpropylimidazolium iodide (DMPII, produced by Shikoku Chemicals Corporation) having a concentration of 0.8 M, and 3-methylpyrazole having a concentration of 0.5 M (produced by Sigma-Aldrich Co. LLC) were dissolved into 3-methoxypropionitrile (3MPL, produced by Sigma-Aldrich Co. LLC), so that the electrolytic solution 42 containing a redox couple was prepared.

### 4. Injecting Electrolytic Solution

The electrolytic solution 42 containing the redox couple was injected from a clearance of the cell to permeate the stacked product. A side face of the cell was sealed with resin. (TB03035B produced by ThreeBond Co., Ltd.) Finally, a lead wire for I-V measurement was attached to each of the electrodes.

### Comparative Example

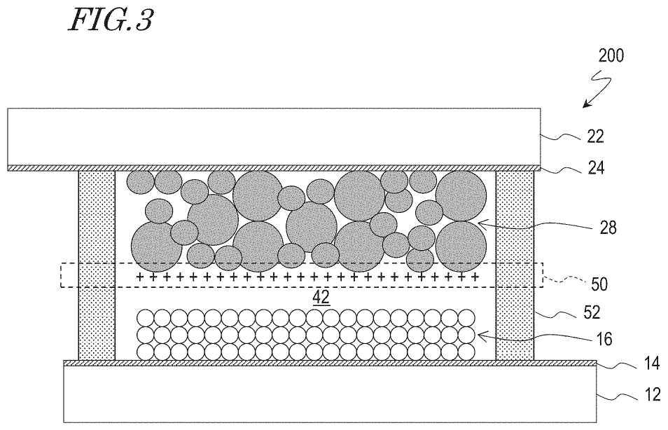

A dye-sensitized solar cell according to a comparative example has the sandwich cell structure illustrated in FIG. 2. The dye-sensitized solar cell of the comparative example was produced in accordance with a production method to be described below.

### 1. Forming Porous Semiconductor Layer

First, a commercially available titanium oxide paste (produced by Solaronix SA under a product name Ti-Nanoxide D/SP with an average particle Size of 13 nm) was applied with a doctor blade to a substrate (produced by Nippon Sheet Glass Company Ltd.) provided with a film of SnO₂ doped with fluorine and serving as the transparent conductive layer 14.

Next, the substrate coated with the titanium oxide paste was preliminarily dried for 30 minutes at a temperature of 100° C., and, after that, baked for 40 minutes at a temperature of 500° C. This step was repeated twice, and the substrate 12 was obtained. The substrate 12 was provided with a titanium oxide film (having a film thickness of 12 μm) serving as the porous semiconductor layer 16.

The FSD 19 dye was dissolved into ethanol, and a dye adsorption solution having a concentration of 4×10⁻⁴ M was prepared. The stacked product was immersed in the dye adsorption solution for 80 hours at a room temperature. After that, the stacked product was washed with ethanol and dried for approximately five minutes at a temperature of approximately 60° C. Thus, a substrate was obtained. The obtained substrate was provided with the porous semiconductor layer 16 carrying the dye.

### 2. Preparing Electrolytic Solution

Iodine having a concentration of 0.05 M (produced by Sigma-Aldrich Co. LLC), dimethylpropylimidazolium iodide (DMPII, produced by Shikoku Chemicals Corporation) having a concentration of 0.8 M, and 3-methylpyrazole having a concentration of 0.5 M (produced by Sigma-Aldrich Co. LLC) were dissolved into 3-methoxypropionitrile (3MPL, produced by Sigma-Aldrich Co. LLC), so that the electrolytic solution 42 containing a redox couple was prepared.

### 3. Forming Counter Electrode Conductive Layer

A vapor deposition apparatus (produced by ULVAC Inc under the name of ei-5) was used to deposit platinum at 0.1 Å/s on the substrate (produced by Nippon Sheet Glass Company Ltd.) 22 provided with a film of SnO₂ doped with fluorine and serving as the transparent conductive layer 24. The counter electrode conductive layer 28 has a film thickness of 0.1 μm.

### 4. Injecting Electrolytic Solution

The counter electrode conductive layer 28 and the porous semiconductor layer 16 were attached together through a spacer to prevent short circuit. The electrolytic solution 42 containing the redox couple was injected into a clearance between the counter electrode conductive layer 28 and the porous semiconductor layer 16. A side face of the cell filled with the electrolytic solution 42 was sealed with resin. (TB03035B produced by ThreeBond Co., Ltd.) Finally, a lead wire for I-V measurement was attached to each of the electrodes.

In the experimental examples, a solar simulator was used to measure a short circuit current Jsc flowing in the DSCs (having a light-receiving area of 5 cm×5 cm) under a normal condition defined by the JIS standard (AM-1.5, a pseudo sunlight of 1 kW/m², a surface temperature of 25° C., and incident light perpendicular to the cell). After that, in compliance with the heat resistance test B-1, the DSCs were left in a constant temperature reservoir at a temperature of 85° C. for 500 hours to obtain a performance retention rate of incident photon-to-current conversion efficiency before and after the heat resistance test.

The measurement was conducted with a solar simulator produced by Wacom Co., Ltd. A secondary reference solar cell was used to adjust the solar irradiance to 1 kW/m². The sample cells of Examples 1 to 5 and Comparative Example were placed in the center of the irradiation face of the solar simulator, and an I-V measurement system (produced by Systemhouse Sunrise Corporation under the name 624SOL3) was connected through a lead wire to the positive electrode and the negative electrode of each of the sample cells. Hence, the performance of the sample cells was evaluated. The constant temperature reservoir for the heat resistance test, SU-261 produced by ESPEC Corporation, was set to 85° C. The samples were left inside the constant temperature reservoir for 500 hours. After that, the performance of the cells was evaluated, using the I-V measurement system.

Described below are features of the sample cells in Examples 1 to 5 and Comparative Example.

### Example 1

Cell structure: Monolithic. Insulating fine particles 36s contained in the porous insulating layer 36A: Zirconium oxide. Pyrazole-based compound: 3-methylpyrazole. Solvent for the electrolytic solution 42: 3-methoxypropionitrile. Counter electrode 28A: Platinum.

### Example 2

Cell structure: Monolithic. Insulating fine particles 36s contained in the porous insulating layer 36A: Titanium oxide (whose average particle size is larger than 400 nm). Pyrazole-based compound: 3-methylpyrazole. Solvent for the electrolytic solution 42: 3-methoxypropionitrile. Counter electrode 28A: Platinum.

### Example 3

Cell structure: Monolithic. Insulating fine particles 36s contained in the porous insulating layer 36A: Zirconium oxide. Pyrazole-based compound: 3-methylpyrazole. Solvent for the electrolytic solution 42: γ-butyrolactone. Counter electrode 28A: Platinum.

### Example 4

Cell structure: Monolithic. Insulating fine particles 36s contained in the porous insulating layer 36A: Zirconium oxide. Pyrazole-based compound: 3-methylpyrazole. Solvent for the electrolytic solution 42: 3-methoxypropionitrile. Counter electrode 28A: Carbon.

### Example 5

Cell structure: Monolithic. Insulating fine particles 36s contained in the porous insulating layer 36A: Zirconium oxide and aluminum oxide. Pyrazole-based compound: 3-methylpyrazole. Solvent for the electrolytic solution 42: 3-methoxypropionitrile. Counter electrode 28A: Platinum.

### Comparative Example

Cell structure: Sandwich. Insulating fine particles contained in the porous insulating layer. None. Pyrazole-based compound: 3-methylpyrazole. Solvent for the electrolytic solution 42: 3-methoxypropionitrile. Counter electrode 28: Platinum.

Table 1 shows effective incident photon-to-current conversion efficiencies A and B (%) and performance retention rates B/A (%) observed at a maximum output point and obtained by the I-V measurement of the samples cells in Examples 1 to 5 and Comparative Example before and after the heat resistance test. As described before, when a DSC is heated at a temperature of approximately 80° C. or above, a redox couple I₃⁻ in the electrolytic solution decomposes into I₂ and I₋. I₂ is adsorbed onto the surface of the porous semiconductor layer formed of titanium oxide, and acts as a current leakage source. As a result, the DSC exhibits a decrease in incident photon-to-current conversion efficiency. Certainly, the DSC in Comparative Example is lower in performance retention rate than the DSCs in Examples 1 to 5.

TABLE 1

| | INCIDENT | INCIDENT | |
|---|---|---|---|
| | PHOTON- | PHOTON- | |
| | TO-CURRENT | TO-CURRENT | |
| | CONVERSION | CONVERSION | PERFORMANCE |
| | EFFICIENCY | EFFICIENCY | RETENTION |
| | A (%) | B IN 500H (%) | RATE = B/A (%) |
| EXAMPLE 1 | 10.1 | 9.1 | 90 |
| EXAMPLE 2 | 10.2 | 8.7 | 85 |
| EXAMPLE 3 | 10.0 | 9.5 | 95 |
| EXAMPLE 4 | 9.1 | 8.9 | 98 |
| EXAMPLE 5 | 9.9 | 9.5 | 96 |
| COMPARATIVE | 9.9 | 4.5 | 45 |
| EXAMPLE | | | |

Whereas, in each of the DSCs in Examples 1 to 5, the pyrazole-based compound permeates throughout the stacked product and forms a complex together with I₂. Such a feature makes it possible to reduce adsorption of I₂ onto the surface of the titanium oxide. The performance evaluation of Examples 1 to 5 showed a significant improvement in reduction of incident photon-to-current conversion efficiency of the DSCs before and after the heat resistance test. When the monolithic cell structure was adopted to the DSCs, the performance retention rate after the heat resistance test reached 98% at a maximum.

The performance retention rate obtained by the measurement of the sample cell in Example 2 is lower than the performance retention rate obtained by the measurement of the sample cell in Example 1. This is probably because the titanium oxide particles having a large average particle size act as the porous insulating layer, and the percentage of I₂ adsorbing onto the surface of the titanium oxide particles is higher than the percentage of I₂ adsorbing onto the surface of the zirconium oxide particles.

The features of the sample cell in Example 3 will be described below more specifically. γ-butyrolactone, a high-permittivity solvent (GBL produced by Kishida Chemical Co., Ltd. and having a relative permittivity of 42), was used as a solvent of the electrolytic solution 42. Among the sample cells in Examples 1 to 3, the sample cell of Example 3 exhibits the highest performance retention rate as a result of the measurement. The use of γ-butyrolactone as the solvent of the electrolytic solution 42 significantly improves solubility of the pyrazole-based compound. The pyrazole-based compound effectively contributes to reaction to I₂. Such a feature makes it possible to appropriately reduce adsorption of I₂ onto the titanium oxide.

The relative permittivity of the electrolytic solution 42 is preferably 20 or higher and 80 or lower. When the relative permittivity falls below 20, the solubility of the pyrazole-based compound in the solvent decreases. Hence, if excessively added, the pyrazole-based compound becomes an aggregate in the electrolytic solution. The aggregated pyrazole-based compound could possibly fail to effectively react to I₂ when the DSC is heated.

Other than γ-butyrolactone, such solvents as ethylene carbonate, propylene carbonate, and γ-valerolactone are expected to significantly improve the solubility of the pyrazole-based compound.

The features of the sample cell in Example 4 will be described below more specifically. As the counter electrode conductive layer 28A, carbon was used instead of platinum. Specifically, a powdered mixture of Ketjen black and graphite (both produced by Nippon Graphite Industries Co., Ltd.) was dispersed into a terpineol solvent to produce a paste containing the powdered mixture. The paste was applied with a doctor blade onto the substrate provided with the titanium oxide film. After that, the substrate 12 coated with the paste of the solvent was preliminarily dried for 30 minutes at a temperature of 100° C., and baked for 40 minutes at a temperature of 400° C.

Even though the carbon material is electrically conductive, the electrical conductivity and the relative permittivity of the carbon material are lower than those of metal. As a result, the positive charges do not appear near the counter electrode. That is why the pyrazole-based compound is kept from being attracted, and is less likely to be eccentrically distributed, toward the counter electrode. Such a feature improves heat resistance of the cell. Among the sample cells in Examples 1 to 5, the sample cell of Example 4 exhibits the highest performance retention rate as a result of the measurement.

The features of the sample cell in Example 5 will be described below more specifically. Instead of zirconium oxide, a layer of mixture including zirconium oxide and aluminum oxide was used as the porous insulating layer 36A. In other words, the insulating fine particles 36s contained in the porous insulating layer 36A include a particle mixture of the zirconium oxide and the aluminum oxide. A mass ratio of the zirconium oxide to the aluminum oxide is 93 to 7.

The measurement result of the experimental examples shows that the performance retention rate obtained by the measurement of the sample cell in Example 5 excels in performance retention rate. As a result, the insulating fine particles 36s contained in the porous insulating layer 36A preferably contain two or more kinds of metal oxide particles with different valences. In other words, the insulating fine particles 36s preferably contain a metal oxide with a first valence and a metal oxide with a second valence smaller than the first valence. An example of a pentavalent metal oxide is niobium oxide. An example of a tetravalent metal oxide is zirconium oxide or titanium oxide. An example of a trivalent metal oxide is aluminum oxide. An example of a divalent metal oxide is magnesium oxide.

Particularly preferably, the metal oxide with the first valence is tetravalent zirconium oxide, and the metal oxide with the second valence is a divalent metal oxide or a trivalent metal oxide. For example, the metal oxide with the second valence is trivalent aluminum oxide or trivalent magnesium oxide.

When metal oxide particles with different valences are in contact with each other, oxygen defects; that is, holes, namely positive electric charges, are created on the contact interfaces of the metal oxide particles having larger valences. Hence, the pyrazole-based compound charged negatively is attracted toward the porous insulating layer 36A, consequently making it possible to reduce eccentric distribution of the pyrazole-based compound near the counter electrode.

Preferably, metal oxide particles with a larger valence (the first valence) are included more in the porous insulating layer 36A than metal oxide particles with a smaller valence (the second valence) are. For example, the insulating fine particles 36s contained in the porous insulating layer 36A include a particle mixture of zirconium oxide and aluminum oxide, and the zirconium oxide particles may be included more in the porous insulating layer 36A than the aluminum oxide particles are. Preferably, the insulating fine particles 36s entirely contain the metal oxide particles with a large valence and the metal oxide particles with a small valence in a mass ratio of 80 to 20 or higher and 99 to 1 or lower. Moreover, the metal oxide particles with a large valence are different in average particle size from the metal oxide particles with a small valence. Preferably, the metal oxide particles with a large valence are larger in average particle size than the metal oxide particles with a small valence. For example, the metal oxide particles with a large valence have an average particle size of 100 μm or larger and 500 μm or smaller, and the metal oxide particles with a small valence have an average particle size of 20 μm or larger and 200 μm or smaller.

### CROSS-REFERENCE TO RELATED APPLICATION

The present application claims priority from Japanese Application JP2019-137939 filed on Jul. 26, 2019, the content of which is hereby incorporated by reference into this application.

1. A dye-sensitized solar cell, comprising:
a first electrode containing first metal oxide particles and including a porous semiconductor layer carrying dye;
a second electrode acting as a counter electrode of the first electrode; and
a porous insulating layer provided between the first electrode and the second electrode, the porous insulating layer (i) holding an electrolytic solution containing a redox couple and a pyrazole-based compound, and (ii) containing second metal oxide particles.

2. The dye-sensitized solar cell according to claim 1, wherein
the pyrazole-based compound is expressed by a general expression below: 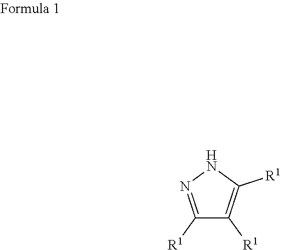
wherein each of elements R¹ is independent and one of substances selected from a group of a hydrogen atom, an alkyl group with 1 to 5 carbons, a halogen group, an amino group, a phenyl group, a furyl group, a methoxyphenyl group, a thienyl group, and a methylphenyl group, and wherein all the elements R¹ are of a single group.

3. The dye-sensitized solar cell according to claim 1, wherein
the second metal oxide particles are larger in average particle size than the first metal oxide particles, and the porous insulating layer is higher in porosity than the porous semiconductor layer.

4. The dye-sensitized solar cell according to claim 1, wherein
the pyrazole-based compound in the electrolytic solution has a molar concentration of 0.3 M or higher and 1.2 M or lower.

5. The dye-sensitized solar cell according to claim 1, wherein
the electrolytic solution includes a solvent having a relative permittivity of 20 or higher and 80 or lower.

6. The dye-sensitized solar cell according to claim 5, wherein
the solvent contains at least one of substances selected from a group of ethylene carbonate, propylene carbonate, γ-butyrolactone, and γ-valerolactone.

7. The dye-sensitized solar cell according to claim 1, wherein
the second electrode includes a counter electrode conductive layer containing carbon fine particles.

8. The dye-sensitized solar cell according to claim 1, wherein
the second metal oxide particles contain at least one of substances selected from a group of zirconium oxide, titanium oxide, niobium oxide, aluminum oxide, and magnesium oxide.

9. The dye-sensitized solar cell according to claim 1, wherein
the second metal oxide particles contain two or more kinds of metal oxide particles with different valences.

10. The dye-sensitized solar cell according to claim 1, wherein
the second metal oxide particles contain metal oxide particles with a first valence and metal oxide particles with a second valence smaller than the first valence.

11. The dye-sensitized solar cell according to claim 10, wherein
the metal oxide particles with the first valence are larger in average particle size than the metal oxide particles with the second valence.

12. The dye-sensitized solar cell according to claim 10, wherein
the metal oxide particles with the first valence are zirconium oxide, and the metal oxide particles with the second valence are divalent metal oxide particles or trivalent metal oxide particles.

13. The dye-sensitized solar cell according to claim 12, wherein
the metal oxide particles with the second valence are aluminum oxide or magnesium oxide.

14. The dye-sensitized solar cell according to claim 10, wherein
the second metal oxide particles entirely contain the metal oxide particles with the first valence and the metal oxide particles with the second valence in a mass ratio of 80 to 20 or higher and 99 to 1 or lower.

15. The dye-sensitized solar cell according to claim 1, further comprising:
a transparent substrate supporting the first electrode; and
a first transparent conductive layer formed on the transparent substrate, and a second transparent conductive layer electrically separated from the first transparent conductive layer and formed on the transparent substrate, wherein
the porous semiconductor layer included in the first electrode is formed on the first transparent conductive layer, and the second electrode is electrically connected to the second transparent conductive layer.

16. The dye-sensitized solar cell according to claim 1, wherein
the porous insulating layer is thinner than the porous semiconductor layer.

17. The dye-sensitized solar cell according to claim 1, wherein
the porous insulating layer has a thickness of 0.2 μm or more and 20 μm or less.
